(19) United States
(12) Patent Application Publication
(10) Pub. No.: US 2014/0338739 A1
(43) Pub. Date: Nov. 20, 2014

(54) INTEGRATED BACK-SHEET FOR BACK CONTACT PHOTOVOLTAIC MODULE

(71) Applicants: Zelin Liu, Shanghai (CN); Qiuju Wu, Shanghai (CN)

(72) Inventors: Zelin Liu, Shanghai (CN); Qiuju Wu, Shanghai (CN)

(73) Assignee: E I DU PONT DE NEMOURS AND COMPANY, Wilmington, DE (US)

(21) Appl. No.: 14/354,238

(22) PCT Filed: Oct. 31, 2011
(86) PCT No.: PCT/CN2011/081551

§ 371 Date: Apr. 25, 2014

(51) Int. Cl. H01L 31/048; H01L 31/05; H01L 31/18; H01L 31/0224

(52) U.S. Cl. CPC H01L 31/0487; H01L 31/022441; H01L 31/0516; H01L 31/1892
USPC 136/256; 136/252; 156/256; 156/233; 438/66

(57) ABSTRACT

An integrated back-sheet for a back contact photovoltaic module is provided. The integrated back-sheet is formed from a polymer substrate and a conductive metal foil that is die cut to provide a metal foil circuit that is adhered to the polymer substrate. A back contact solar cell module incorporating the integrated back-sheet with the die cut metal foil circuit is also provided. Processes for forming such integrated back-sheets and back contact solar cell modules are also provided.

### FIELD OF THE INVENTION

The present invention relates to back-sheets for photovoltaic cells and modules, and more particularly to back-sheets with integrated electrically conductive circuitry, and to processes for making back-sheets with integrated electrically conductive circuits, and to processes for making back-contact photovoltaic modules with such integrated back-sheets.

### BACKGROUND OF THE INVENTION

A photovoltaic cell converts radiant energy, such as sunlight, into electrical energy. In practice, multiple photovoltaic cells are electrically connected together in series or in parallel and are protected within a photovoltaic module or solar module.

As shown in FIG. 1, a photovoltaic module 10 comprises a light-transmitting substrate 12 or front sheet, an encapsulant layer 14, an active photovoltaic cell layer 16, another encapsulant layer 18 and a back-sheet 20. The light-transmitting substrate is typically glass or a durable light-transmitting polymer film. The encapsulant layers 14 and 18 adhere the photovoltaic cell layer 16 to the front and back sheets and they seal and protect the photovoltaic cells from moisture and air and they protect the photovoltaic cells against physical damage. The encapsulant layers 14 and 18 are typically comprised of a thermoplastic or thermosetting resin such as ethylene-vinyl acetate copolymer (EVA). The photovoltaic cell layer 16 may be any type of photovoltaic that converts sunlight to electric current such as single crystal silicon solar cells, polycrystalline silicon solar cells, microcrystal silicon solar cells, amorphous silicon-based solar cells, copper indium (gallium) diselenide solar cells, cadmium telluride solar cells, compound semiconductor solar cells, dye sensitized solar cells, and the like. The back-sheet 20 provides structural support for the module 10, it electrically insulates the module, and it helps to protect the solar cells, module wiring and other components against the elements, including heat, water vapor, oxygen and UV radiation. The module layers need to remain intact and adhered for the service life of the photovoltaic module, which may extend for multiple decades.

Photovoltaic cells typically have electrical contacts on both the front and back sides of the photovoltaic cells. However, contacts on the front sunlight receiving side of the photovoltaic cells can cause up to a 10% shading loss. In back contact photovoltaic cells, all of the electrical contacts are moved to the back side of the photovoltaic cell. With both the positive and negative polarity electrical contacts on the back side of the photovoltaic cell, electrical circuitry is needed to provide electrical connections to the positive and negative polarity electrical contacts on the back of the photovoltaic cell.

U.S. Patent Application No. 2011/0067751 discloses a back contact photovoltaic module with a back-sheet having patterned electrical circuitry that connects to the back contacts on the photovoltaic cell during lamination of the solar module. The circuitry is formed from a metal foil that is adhesively bonded to a carrier material such as polyester fill or Kapton® film. The carrier material may be adhesively bonded to a protective layer such as a Tedlar® fluoropolymer film. The foil is patterned using etching resists that are patterned on the foil by photolithography or by screen printing according to techniques used in the flexible circuitry industry. A protective layer is applied over the remaining foil circuits using a solder mask or cover lay. An interlayer dielectric (ILD) is patterned over the circuit, typically by screen printing a polymeric material, and openings are formed in the ILD where the back contacts on the photovoltaic cell are to contact the foil circuits. A thermoplastic or thermosetting encapsulant sheet, typically an EVA sheet, is placed over the ILD with openings punched out at locations corresponding to the openings in the ILD. A conductive adhesive is applied in the ILD openings. The back contact photovoltaic cell is placed on the encapsulant layer using pick and place technology such that the back contacts on the photovoltaic cell align with the openings in the ILD and encapsulant sheet. The back contacts on the photovoltaic cell are adhered to and electrically connected to the foil circuits by the adhesive conductive paste.

Bonding the metal foil to a carrier material, patterning the metal foil using etching resists that are patterned by photolithography or screen printing, and adhering the carrier material to one or more protective back-sheet layers can be expensive and time consuming and can use processes that result in significant liquid waste. There is a need for a more efficient process for producing a back-sheet with integrated conductive circuitry for a back contact photovoltaic cell or module.

### SUMMARY OF THE INVENTION

A process for forming an integrated back-sheet for a back contact photovoltaic module comprises the steps of providing a polymer substrate and a conductive metal foil, die cutting the conductive metal foil to separate the metal foil into two or more conductive metal foil sections, removing one or more of the conductive metal foil sections to form one or more patterned metal foil circuits from the remaining metal foil, and adhering the conductive metal foil circuits to the polymer substrate.

In one embodiment, the conductive metal foil is adhered to the polymer substrate before the conductive metal foil is die cut into two or more conductive metal foil sections, and preferably the die cutting of the conductive metal foil does not cut through the polymers substrate. In another embodiment, the conductive metal foil may be die cut into two or more conductive metal foil sections, and one or more of sad conductive metal foil sections may be removed to form one or more patterned metal foil circuits, and the one or more patterned metal circuits may be subsequently adhered to the polymer substrate. The conductive metal foil may be adhered to a transfer sheet prior to the steps of die cutting the metal foil and removing the one or more of said conductive metal foil sections to form one or more patterned metal foil circuits from the remaining metal foil, and after the steps die cutting the conductive metal foil and removing the one or more of the conductive metal foil sections to form one or more patterned metal foil circuits from the remaining metal foil, the patterned metal foil circuit may be transferred from the transfer sheet and adhered to the polymer substrate.

The conductive metal foil is preferably adhered to the polymer substrate by a thermoplastic adhesive extruded between said conductive metal foil and said polymer substrate. The conductive metal foil is preferably adhered to the polymer substrate by an extruded ethylene copolymer adhesive layer. The ethylene copolymer layer may be extruded onto one of the polymer substrate, the conductive metal foil, or both the polymer substrate and the conductive metal foil in order to adhere the conductive metal foil to the polymer substrate.

A preferred embodiment further comprises the steps of providing an interlayer dielectric layer and in any order, die cutting the interlayer dielectric layer to form holes in interlayer dielectric layer, and adhering the interlayer dielectric layer over one or more of the patterned metal circuits that are adhered to the polymer substrate wherein the holes in the interlayer dielectric layer are aligned with the patterned metal foil circuits.

In one embodiment, the polymer substrate preferably comprises a polyester layer having opposite first and second sides, wherein the first side of the polyester layer is adhered to conductive metal foil by an extruded ethylene copolymer layer. The polymer substrate may further comprise a fluoropolymer layer adhered to the second side of said polyester layer.

The conductive metal foil is preferably comprised of one or more metals selected from aluminum, tin, copper, nickel, silver, gold, tin coated copper, silver coated copper, gold coated copper, steel, invar, and alloys thereof. The conductive metal foil preferably has a thickness of 5-50 microns, and optionally 8-40 microns.

A process for forming a back contact solar module is also disclosed in which the integrated back-sheet as described above is provided along with a back contact photovoltaic cell having a front side and a back side, and having electrical contacts on the back side of the photovoltaic cell, and the electrical contacts on the back side of the photovoltaic cell are electrically connected to the one or more patterned metal foil circuits adhered to polymer substrate. The process may further comprise the steps of adhering an interlayer dielectric layer over one or more of the patterned metal circuits, die cutting the interlayer dielectric layer to separate the interlayer dielectric layer into two or more interlayer dielectric layer sections without cutting the one or more patterned metal circuits the same time, and peeling one or more of the interlayer dielectric layer sections from the patterned metal circuit to create one or more holes in the interlayer dielectric layer through which one or more of the patterned metal circuits are exposed, and adhering the back side of the photovoltaic cell to the interlayer dielectric layer in a manner that one or more of the electrical contacts on the back side of the photovoltaic cell are electrically connected to one of the patterned metal circuits on the polymer substrate through one of the holes in the interlayer dielectric layer.

In the process for forming a back contact solar module, the electrical contacts on the back side of the photovoltaic cell may be electrically connected to one of the patterned metal circuits adhered to the polymer substrate through one of the holes in the interlayer dielectric layer by an electrically conductive adhesive or by solder. An encapsulant layer may be applied to the back side of the photovoltaic cell where the encapsulant layer has openings corresponding to the electrical contacts on the back side of the photovoltaic cell.

An integrated back-sheet for a back contact photovoltaic module is also provided. The back-sheet comprises a polymer substrate and a die cut metal foil circuit adhered to the polymer substrate by an extruded thermoplastic adhesive layer between the polymer substrate and the die cut metal foil circuit. The patterned metal foil circuit is characterized by edges having side surfaces with a root-mean-square (RMS) roughness value of less than about 40 nm within a 5×5 μm² area and measured by atomic force microscopy. A back contact solar cell module comprising such an integrated back-sheet is also provided. The module also comprises a back contact photovoltaic cell having a front side and a back side, the photovoltaic cell having electrical contacts on the back side of the photovoltaic cell, an interlayer dielectric layer between the patterned metal foil circuit of the integrated back-sheet and the electrical contacts on the back side of the back contact photovoltaic cell. The interlayer dielectric layer has one or more holes aligned over one or more of the patterned metal foil circuits, wherein the electrical contacts on the back side of the photovoltaic cell are electrically connected to one or more of the patterned metal foil circuits through the holes in the interlayer dielectric layer.

### BRIEF DESCRIPTION OF THE DRAWINGS

The detailed description will refer the following drawings which are not drawn to scale and where like numerals refer to like elements:

FIG. 1 is a cross-sectional view of a conventional photovoltaic module;

FIG. 2 is a schematic illustration of a disclosed method for forming an integrated back-sheet.

FIG. 3 is a partial cross-sectional view of the die-cutting step of the process shown in FIG. 2.

FIG. 4a is a plan view of a metal foil laminated on a polymer substrate.

FIG. 4b is a plan view of the metal foil of FIG. 4a after it has been die-cut and before removal of waste foil.

FIG. 4c is a plan view of the metal foil of FIG. 4b after it has been die-cut and waste foil has been removed. The “+” and “−” signs represent positions where the metal for may be adhered to the positive and negative back contacts of back-contact photovoltaic cells.

FIG. 4d is a plan view of an encapsulant layer with holes or passages therein.

FIG. 4e is a plan view of the integrated back-sheet FIG. 4d in which the underlying die cut foil layer is shown.

FIG. 4f is a plan view of the foil layer of FIG. 4c with the position of the overlying solar cells shown in dashed lines.

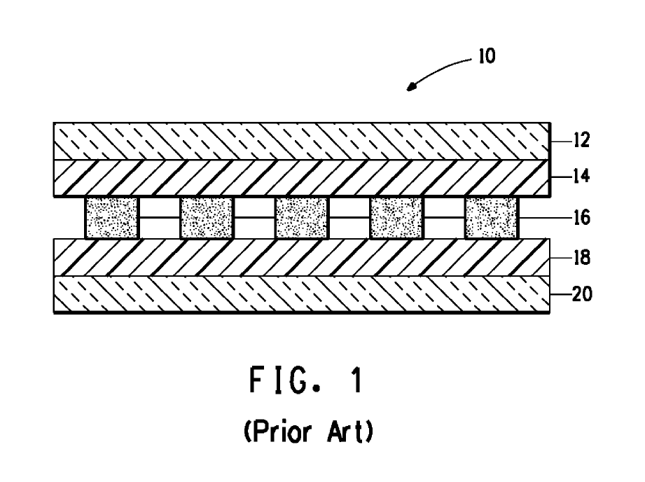

### DETAILED DESCRIPTION OF THE INVENTION

To the extent permitted by the applicable patent law, all publications, patent applications, patents, and other references mentioned herein are incorporated by reference in their entirety.

The materials, methods, and examples herein are illustrative only and the scope of the present invention should be judged only by the claims.

### Definitions

The following definitions are used herein to further define and describe the disclosure.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

As used herein, the terms “a” and “an” include the concepts of “at least one” and “one or more than one”.

Unless stated otherwise, all percentages, parts, ratios, etc., are by weight.

When the term “about” is used in describing a value or an end-point of a range, the disclosure should be understood to include the specific value or end-point referred to.

As used herein, the terms “sheet”, “layer” and “film” are used in their broad sense interchangeably. A “frontsheet” is a sheet, layer or film on the side of a photovoltaic module that faces a light source and may also be described as an incident layer. Because of its location, it is generally desirable that the frontsheet has high transparency to the desired incident light. A “back sheet” is a sheet, layer or film on the side of a photovoltaic module that faces away from a light source, and is generally opaque. In some instances, it may be desirable to receive light from both sides of a device (e.g., a bifacial device), in which case a module may have transparent layers on both sides of the device.

“Encapsulant” layers are used to encase the fragile voltage-generating photoactive layer to protect it from environmental or physical damage and hold it in place in the photovoltaic module. Encapsulant layers may be positioned between the solar cell layer and the incident layer, between the solar cell layer and the back-sheet layer, or both. Suitable polymer materials for the encapsulant layers typically possess a combination of characteristics such as high transparency, high impact resistance, high penetration resistance, high moisture resistance, good ultraviolet (UV) light resistance, good long term thermal stability, adequate adhesion strength to frontsheets, backsheets, other rigid polymeric sheets and cell surfaces, and good long term weatherability.

As used herein, the terms “photoactive” and “photovoltaic” may be used interchangeably and refer to the property of converting radiant energy (e.g., light) into electric energy.

As used herein, the terms “photovoltaic cell” or “photoactive cell” or “solar cell” mean an electronic device that converts radiant energy (e.g., light) into an electrical signal. A photovoltaic cell includes a photoactive material layer that may be an organic or inorganic semiconductor material that is capable of absorbing radiant energy and converting it into electrical energy. The terms “photovoltaic cell” or “photoactive cell” or “solar cell” are used herein to include photovoltaic cells with any types of photoactive layers including, crystalline silicon, polycrystalline silicon, microcrystal silicon, and amorphous silicon-based solar cells, copper indium (gallium) diselenide solar cells, cadmium telluride solar cells, compound semiconductor solar cells, dye sensitized solar cells, and the like.

As used herein, the term “photovoltaic module” or “solar module” (also “module” for short) means an electronic device having at least one photovoltaic cell protected on one side by a light transmitting front sheet and protected on the opposite side by an electrically insulating protective back-sheet.

As used herein, terms “die-cut” and “die-cutting” refer to a manufacturing process wherein one or more blades of a desired shape slice through one or more layers of a material such as wood, plastic, paper, metal or fabric to produce cut shapes of material, and includes die-cutting done on flat, rotary or multiple-step presses, as well as by laser cutting.

As used herein, the term “pick-and-place” is a term of art and refers to an assembly process in which components are selected and placed onto specific locations according an assembly file.

Disclosed are an integrated back sheet for a back contact photovoltaic cell and processes for forming integrated back-sheets. In the disclosed process, a polymer substrate and a conductive metal foil are provided. The conductive metal foil is die-cut into two or more conductive metal foil sections. One or more of the conductive metal foil sections is peeled from the remainder of the foil to form one or more patterned metal foil circuits. The conductive metal foil is adhered to the polymer substrate. In one embodiment, the conductive metal foil is adhered to the polymer substrate after which the metal foil is die cut without cutting through the polymer substrate. In another embodiment, the metal foil is adhered to a transfer sheet, die cut, and then adhered to the polymer substrate. In another embodiment, a self-supporting metal foil is die cut to produce a self supporting foil circuit that is subsequently adhered to the polymer substrate.

Also disclosed is a photovoltaic module with an integrated back-sheet and a process for forming such photovoltaic modules. According to the disclosed process, a back contact photovoltaic cell having a front side and a back side is provided where the photovoltaic cell has electrical contacts on the back side of the photovoltaic cell and the electrical contacts on the back side of the photovoltaic cell are electrically connected to one or more patterned foil metal circuits on the integrated back-sheet made according to the described processes.

One disclosed process for forming an integrated back-sheet for a back contact photovoltaic cell further comprises the steps of adhering an interlayer dielectric layer over one or more of the patterned metal circuits, and die cutting the interlayer dielectric layer to separate the interlayer dielectric layer into two or more sections without cutting through the one or more patterned metal circuits at the same time. One or more of the interlayer dielectric layer sections are peeled from the patterned metal circuit to create one or more holes in the interlayer dielectric layer through which one or more of the patterned metal circuits are exposed.

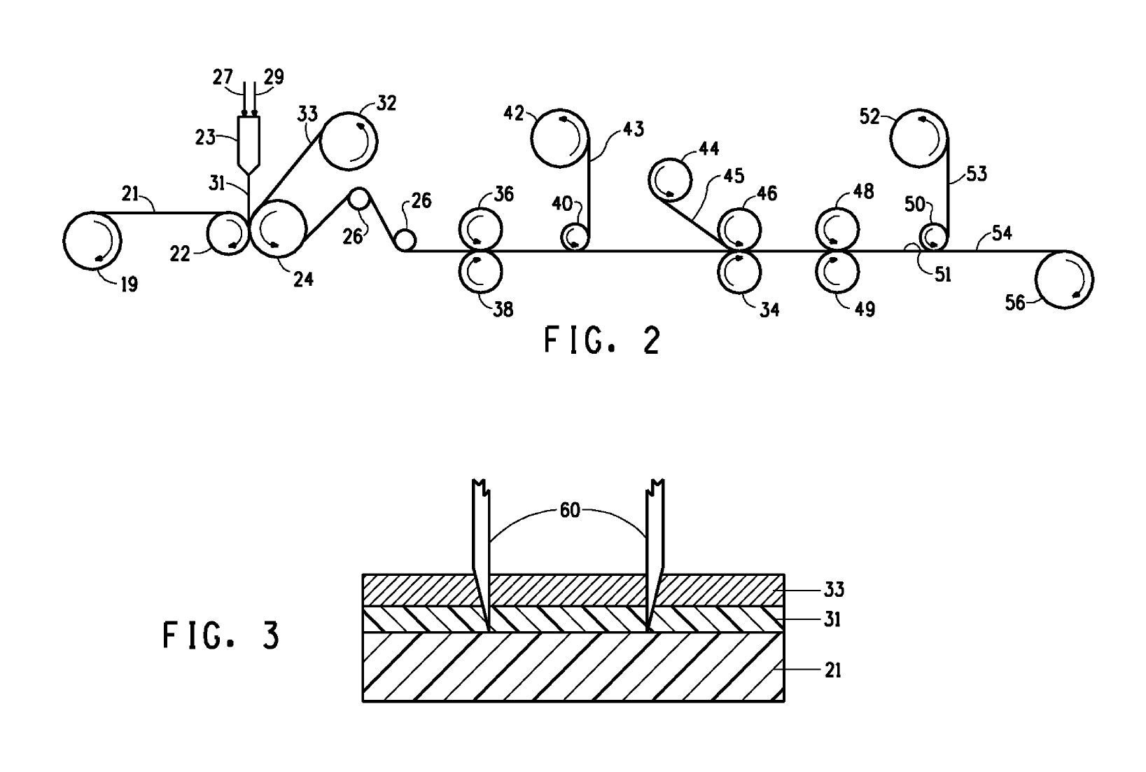

A process for making an integrated back-sheet for a back contact photovoltaic cell is schematically shown in FIG. 2. For purposes of illustration, FIG. 2 shows a continuous roll-to-roll process for producing an integrated back sheet. It is contemplated that the process could be broken up into multiple sub-processes that are preformed separately, as for example, where the equipment for performing the various portions of the overall process are at different locations.

In the process for forming an integrated back-sheet for a back contact photovoltaic module shown in FIG. 2, a polymer substrate 21 is provided from a supply roll 19. The polymer substrate may be comprised of polymeric material, optionally in conjunction with other materials, used in photovoltaic back-sheets. The polymeric substrate may comprise a polymer film, sheet or laminate that is used as a back-sheet in conventional photovoltaic modules. The polymeric substrate may, for example, be comprised of film comprised of one or more of polyester, fluoropolymer, polycarbonate, polypropylene, polyethylene, cyclic polyolefin, acrylate polymer such as polymethylmethacrylate (PMMA), polystyrene, styrene-acrylate copolymers, acrylonitrile-styrene copolymers, poly(ethylene naphthalate), polyethersulfone, polysulfone, polyamide, epoxy resin, glass fiber reinforced polymer, carbon fiber reinforced polymer, acrylics, cellulose acetates, vinyl chloride polymers, polyvinylidene chloride, vinylidene chloride copolymers, and the like. The polymeric substrate may also comprise laminates of such polymer films. The layers of such laminates may be adhered to each other by adhesives between the layers or by adhesives incorporated into one or more of the laminate layers. Laminates of polyester films and fluoropolymer are especially suitable for the polymer substrate. Suitable polyesters include polyethylene terephthalate (PET), polytrimethylene terephthalate, polybutylene terephthalate, polyhexamethylene terephthalate, polyethylene phthalate, polytrimethylene phthalate, polybutylene phthalate, polyhexamethylene phthalate or a copolymer or blend of two or more of the above. Suitable fluoropolymers include polyvinylfluoride (PVF), polyvinylidene fluoride, polytetrafluoroethylene, ethylene-tetrafluoroethylene copolymers and combinations thereof. In one embodiment, the polymeric substrate comprises a bi-axially oriented PET film adhered to a PVF film.

There are no specific restrictions on the thickness of the polymeric substrate or on the various polymer film layers of the polymeric substrate. Thickness varies according to specific application. In one preferred embodiment, the polymeric substrate comprises a fluoropolymer layer with a thickness in the range of 20-50 μm adhered to a PET film with a thickness of 50-300 μm.

Various known additives may be added to the polymer layer(s) of the polymeric substrate to satisfy various different requirements. Suitable additives may include, for example, light stabilizer, UV stabilizers, thermal stabilizers, anti-hydrolytic agents, light reflection agents, pigments, titanium dioxide, dyes, and slip agents.

The polymeric films of the polymeric substrate may include one or more non-polymeric layers or coatings such as a metallic, metal oxide or non-metal oxide surface coating. Such coatings are helpful for reducing moisture vapor transmission through a back-sheet structure. The thickness of such a metallic, metal oxide layer or non-metal oxide layer on one or more of the polymer films typically measures between 50 Å and 4000 Å, and more typically between 100 Å and 1000 Å.

In the disclosed process, the polymeric substrate 21 is adhered to a metal foil 33. The metal foil is a conductive metal foil such as foil of aluminum, tin, copper, nickel, silver, gold, tin coated copper, silver coated copper, gold coated copper, steel, invar, and alloys thereof. Aluminum foil and copper foil are most commonly selected on the basis of cost and other factors. The thickness of the foil is in the range of 5-50 μm, or preferably 8-40 μm. In one embodiment, a 35 μm thick copper foil is adhered to the polymeric substrate. Examples of suitable foils include a 30 μm thick copper foil (type: THE-T9FB) from Suzhou Fukuda Metal Co., Ltd of Suzhou, China, and a 30 μm thick MHT copper foil from OAK-MITSUI LLC, of Hoosick Falls, N.Y., USA.

In the process shown in FIG. 2, the polymeric substrate is adhered to the metal foil by means of an extruded thermoplastic adhesive. Preferred thermoplastic adhesives include ethylene copolymers, acrylic polymers and copolymers, polymethyl methacrylate, polyesters, and blends of such polymers.

Ethylene copolymer adhesives useful for adhering the polymeric substrate to the metal foil are more fully disclosed in PCT Patent Publication No. WO2011/044417 which is hereby incorporated by reference. Preferred ethylene copolymer adhesives are comprised of ethylene and one or more monomers selected from the group of consisting of C1-4 alkyl acrylates, C1-4 alkyl methacrylates, methacrylic acid, acrylic acid, glycidyl methacrylate, maleic anhydride and copolymerized units of ethylene and a comonomer selected from the group consisting of C4-C8 unsaturated anhydrides, monoesters of C4-C8 unsaturated acids having at least two carboxylic acid groups, diesters of C4-C8 unsaturated acids having at least two carboxylic acid groups and mixtures of such copolymers, wherein the ethylene content in the ethylene copolymer preferably accounts for 60-90% by weight. The ethylene copolymer used in the adhesive layer may include a copolymer of ethylene and another olefin. The ethylene content in the copolymer may account for 60-90% by weight, preferably accounting for 65-88% by weight, and ideally accounting for 70-85% by weight of the ethylene copolymer. The other comonomer(s) preferably constitute 10-40% by weight, more preferably accounting for 12-35% by weight, and ideally accounting for 15-30% by weight of the ethylene copolymer. The ethylene copolymer adhesive layer is preferably comprised of at least 70 weight percent of the ethylene copolymer. The ethylene copolymer may be blended with up to 30% by weight, based on the weight of the adhesive layer, of other thermoplastic polymers such as polyolefins, as for example linear low density polyethylene, in order to obtain desired properties.

Ethylene copolymers are commercially available. For example, one may be purchased from E. I. du Pont de Nemours and Company under the trade-name Bynel®.

Various known additives and fillers may be added to the thermoplastic adhesive to satisfy various different requirements. Suitable additives and fillers may include, for example, light stabilizer, UV stabilizers, thermal stabilizers, anti-hydrolytic agents, light reflection agents, pigments, titanium dioxide, dyes, slip agents, and calcium carbonate. There are no specific restrictions to the content of the additives and fillers in the thermoplastic adhesive as long as the additives do not produce an undue adverse impact on the extruded adhesive or final adhesion of the metal foil to the polymeric substrate.

There are no specific restrictions on the thickness of the thermoplastic adhesive described herein. Thickness varies according to specific application. In one preferred embodiment, the thermoplastic adhesive is an ethylene copolymer film with a thickness in the range of 10-400 μm, and is preferably in the range of 30-200 μm.

The thermoplastic adhesive layer itself may also be a two-layer, three-layer or multilayer material. As shown in FIG. 2, the extruded thermoplastic film 31 may comprise coextruded layers comprised of one thermoplastic adhesive 27 formulated to adhere to the surface of the polymeric substrate 21 and another thermoplastic adhesive 29 formulated to adhere to the foil 33. As seen in FIG. 2, the thermoplastic adhesive may be extruded from the coextruder 23 onto the surface of the polymeric substrate 21, as for example a PET layer, just as the polymeric film enters a nip formed between the rollers 22 and 24, and just before or as the foil 33 enters the nip. Preferably the thermoplastic adhesive is extruded at a temperature in the range of 230-300° C. such that the adhesive film 31 is sandwiched between the polymeric substrate 21 and the metal foil 33. The roller surface temperature is in the range of 10-100° C., and preferably in the range of 18-30° C. At least one of the rollers 22 and 24 preferably heated such that the thermoplastic adhesive and the metal foil are adhered well to each other. The metal foil may be preheated with heaters or another heated roll to promote adhesive bonding between the metal foil and the thermoplastic adhesive. In an alternative embodiment, the thermoplastic adhesive layer 31 may be extruded onto the polymeric substrate 21 and passed between a nip to adhere the thermoplastic adhesive to the polymeric substrate, and the polymeric substrate with thermoplastic adhesive coating can be transported to another nip or location where the metal foil is brought into contact and adhesive engagement with the thermoplastic adhesive film. If the bonding strength between adhesive layer and metal foil is stronger than that between adhesive layer and the polymeric substrate, the metal foil plus the adhesive layer will be removed after die cutting, if the bonding strength between adhesive layer and metal foil is weaker than that between adhesive layer and the polymeric substrate, then only the metal foil will be removed after die cutting.

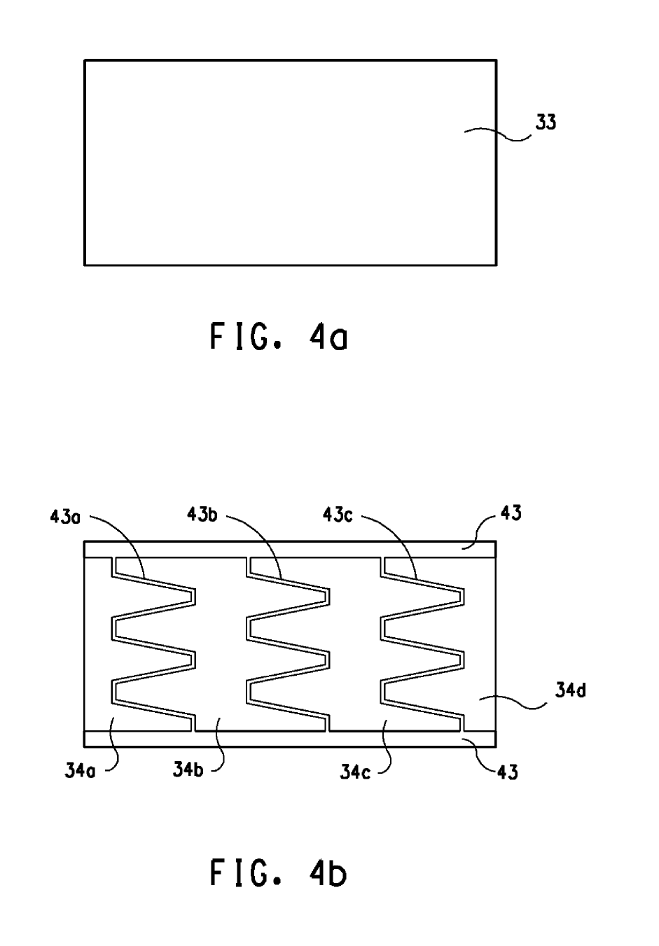

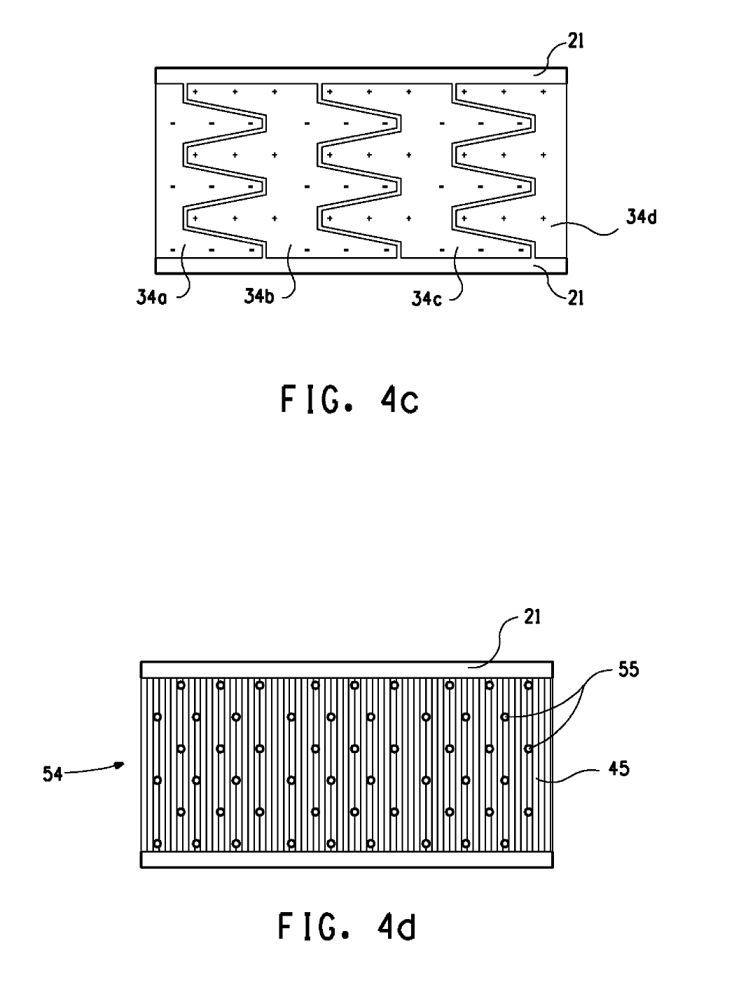

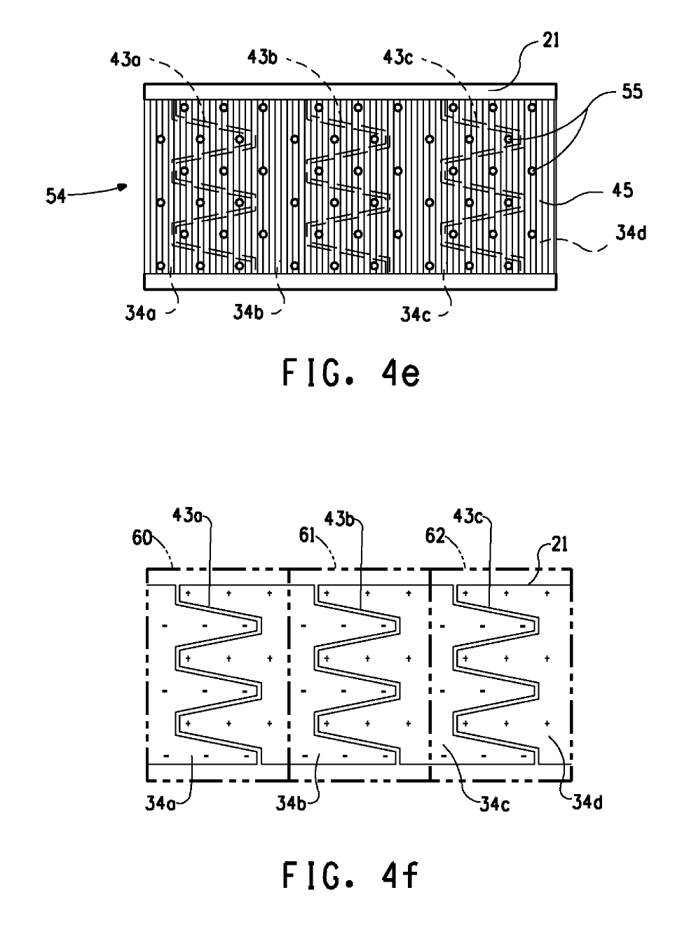

A plan view of the metal foil 33 adhered on the polymeric substrate is shown in FIG. 4a. As shown in FIG. 2, the polymeric substrate/thermoplastic adhesive/metal foil laminate is carried by the transport rollers 26 to a rotary die-cutting machine represented schematically by the cutting roll 36 and the backing roll 38. The die cutting of the conductive metal foil separates the metal foil into two or more conductive metal foil sections, and more preferably into three or more sections. In the roll-to-roll process shown in FIG. 2, the die-cutting machine is a rotary die cutting press. Where the die-cutting portion of the process is run as a separate batch process, a flat die cutting press may be utilized. The major component of the die-cutting machine is a cut die, which could be a rotary die, flat die, or male/female die. For a flat die, the blade would be positioned above the sample. A flat die has a low cost and is easy to operate. The die-cutting machine may also include a feeding device, a collection device, a digital monitor, slitting equipment, waste stripping equipment, and/or calibration equipment. For example, an F-400A die cutting machine, an MX7-250-130 rotary die cutting machine, or an L-1350 large-size die cutting machine from Dongguan FEIXINDA Precision Machinery Science & Technology Co., Ltd. Dongguan, China, may be utilized. A partial cross-sectional view of the die cutting step is shown in FIG. 3. The die cutting blades 60 cut the metal foil 33 and the thermoplastic adhesive layer 31, but they do not cut through the polymeric substrate 21. Preferably, the die cutting blades 60 do not cut significantly into the polymeric substrate 21, and more preferably do not cut the polymeric substrate 21 at all.

One or more of the conductive metal foil sections are peeled from the polymer substrate to form one or more patterned metal circuits on the polymer substrate from the remaining metal foil. Select portions of the metal foil, and optionally the adhered thermoplastic adhesive, are lifted from the laminate structure at the roll 40 and collected on the waste take up roll 42. For example, where the circuit pattern is like the circuits 34 shown in FIG. 4b, the waste portions 43 are continuous patterns, which can be peeled off continuously. The starting point of the waste edge portions 43 are fixed on the roll 42 by adhesive ribbons, so that during the process, the roll 42 collects the waste portions continuously.

FIG. 4b shows a plan view of a metal foil that has been died cut into multiple sections and the die cut foil sections 34a, 34b, 34c and 34d are between the die cut foil waste sections 43, 43a, 43b and 43c that are to be peeled from the foil. The circuit pattern in FIG. 4b is made by a patterned blade or a combination of blades similar to the blade shown in FIG. 3. Section 43a, 43b, and 43c form a connected domain connected by the waste edges 43. FIG. 4c shows the die-cut foil circuit pattern after removal of the foil waste portions 43. The “+” and “−” signs in FIG. 4c represent where positive and negative polarity contacts on the back side of a back contact solar cell will be electrically connected to the various circuits formed from the die cut metal foil. The connections shown by the “+” and “−” signs are for the contacts of an array of photovoltaic cells that are connected in series such that positive contacts on one call connect to negative contacts on another cell, as more fully described below with regard to FIG. 4e.

In an alternative embodiment, the metal foil 33 is first adhered to transfer sheet (protective film) such as a polyester sheet coated with a pressure sensitive adhesive. The metal foil is then die cut to separate the foil into two or more sections by a die cutting process like the die cutting processes described above. Die cut sections are peeled from the transfer sheet so as to divide the metal foil into separate sections as described above with regard to FIG. 4b. A polymer substrate is prepared for receiving the die cut metal foil by extruding a coating of a thermoplastic adhesive onto the surface of the polymer substrate. The extruded thermoplastic adhesive may be comprised of any of the thermoplastic adhesives as describe above. The extruded thermoplastic adhesive layer typically has a thickness in the range of 5-300 μm and preferably in the range of 20-100 μm. The die cut metal foil on the transfer sheet is brought into contact with the extruded thermoplastic adhesive and adhered to the thermoplastic adhesive on the polymeric substrate. The adhesion may be accomplished by passing the polymeric substrate/thermoplastic adhesive/metal foil on transfer film through a heated nip to adhere the die cut foil to the thermoplastic adhesive and polymer substrate. Finally the transfer sheet is peeled from the die cut metal foil circuit by a rewind roll. The transfer sheet easily peels from the foil because the transfer sheet is weakly bonded to the metal toll whereas the thermoplastic adhesive is much more strongly bonded to the die cut metal foil.

In another embodiment, a self supporting foil is die cut without being adhered to a transfer sheet. The die-cut circuit is a continuous pattern such that the circuit may be die cut and collected for subsequent lamination to the polymeric substrate. The self-supporting die-cut foil circuit may be adhered to the polymeric substrate by extruding a thermoplastic adhesive between the polymeric substrate and the die-cut foil and then passing the laminate through a heated nip as described above, or by means of a heated press.

An interlayer dielectric layer (ILD) may be applied over the die cut metal foil. The ILD layer is made of an electrically insulating material, and may be comprised dielectric materials used in the electronics industry. The ILD layer is provided to maintain a sufficient electrical separation between the metal foil and the backs of the solar cells. Suitable dielectric materials include polymer substrates, such as thermoplastic or thermoset polymer layers. Polymeric materials that make suitable ILD layers include films comprised of polyester, polyethylene, polypropylene, fluoropolymer, ethylene copolymer, poly acrylate, polymethyl methacrylate, acylic polymer, or epoxy resin. The ILD layer may also be screen printed on the die cut metal foil. The ILD layer preferably has a thickness of about 5 to 500 microns, and preferably of about 10 to 200 microns, and more preferably of about 25 to 200 microns. Preferably, the ILD is comprised of a material that can be die cut or punched, or that can be formed with openings in it. The ILD may be made of a material with adhesive properties or the ILD may be coated with an adhesive, such as a pressure sensitive adhesive, on the side(s) that will be engage with the die cut metal foil or rear surface of solar cells. In one embodiment, the ILD layer is comprised of a PET polymer film coated with an ethylene copolymer adhesive layer for adhering the PET film to the die cut metal foil. In another embodiment, the ILD is a PET film laminated to an encapsulant layer such as an EVA film.

Preferred encapsulants for use in photovoltaic modules are typically comprised of an ethylene methacrylic acid or ethylene acrylic acid copolymer, an ionomer derived therefrom, or a combination thereof. The encapsulant layer or layers typically have a thickness greater than or equal to 20 mils (508 microns). Such encapsulant layers may be films or sheets comprising poly(vinyl butyral) (PVB), ionomers, ethylene vinyl acetate (EVA), poly(vinyl acetal), polyurethane (PU), PVC, metallocene-catalyzed linear low density polyethyenes, polyolefin block elastomers, ethylene acrylate ester copolymers, such as poly(ethylene-co-methyl acrylate) and poly(ethylene-co-butyl acrylate), acid copolymers, silicone elastomers and epoxy resins. The ILD and encapsulant layer(s) may further contain any additive known within the art. Such exemplary additives include, but are not limited to, plasticizers, processing aides, flow enhancing additives, lubricants, pigments, dyes, flame retardants, impact modifiers, nucleating agents to increase crystallinity, antiblocking agents such as silica, thermal stabilizers, hindered amine light stabilizers (HALS), UV absorbers, UV stabilizers, dispersants, surfactants, chelating agents, coupling agents, adhesives, primers, reinforcement additives, such as glass fiber, fillers and the like.

Preferably the ILD layer or the ILD layer/encapsulant layer laminate is comprised of a material that can be die cut. The ILD layer is preferably coated with an adhesive on the side of the ILD layer that will come into contact with the metal foil. Suitable adhesive coatings on the ILD layer include pressure sensitive adhesives, thermoplastic adhesives as discussed above such as the ethylene copolymer adhesives and ethylene vinyl acetate. As shown in FIG. 2, an ILD layer 45 may be provided from a supply roll 44 and adhered to the die cut metal foil 33 by an adhesive layer (not shown) on the surface of the ILD layer that faces the metal foil. The polymeric substrate/thermoplastic adhesive/die cut metal foil/ILD layer laminate is passed between the nip rolls 34 and 46 in order to adhere the ILD layer 45 to the metal foil 33. One or both of the nip rolls may be heated in order to promote adhesion between the ILD layer and the metal foil.

The ILD layer 45 may be provided with precut or preformed via holes for aligning with the electrical contacts on the back side of a solar cell. For example, where the IDL is screen printed, it may be printed with openings. Where the ILD is a film, the openings may be cut in the ILD layer by stamping or cutting with a blade or laser. In the embodiment shown in FIG. 2, the ILD layer 45 is applied to the metal foil 33 and subsequently die cut by passing the polymeric substrate/thermoplastic adhesives/die cut metal foil/ILD layer laminate through a die cutting press such as a die cutting roller 48 that works with a back up roller 49 to die cut via holes or passages in the ILD layer, but that does not cut the metal foil layer. The holes that are die cut in the ILD layer may be removed from the dielectric layer by stripping the waste components, as for example, by using stripping roll 50 to collect the waste portion on a waste collection sheet 53 that is collected on the take up roller 52. The polymeric substrate thermoplastic adhesive die cut metal foil/ILD layer laminate that form the integrated back sheet 54 is subsequently collected on the back-sheet collection roller 56.

A plan view of the integrated back-sheet 54 is shown in FIG. 4d which shows the ILD layer 45 with cut holes 55. In FIG. 4e, the ILD layer 45 is shown with the holes 55 superposed over the underlying metal foil layer from which the die cuts 43a 43b and 43c have been removed to create multiple foil circuits. Alternating rows of three holes are positioned relative to the die cuts 43 so that the alternating rows of three holes align with foil sections on opposite sides of the die cuts 43a, 43b and 43c. In FIG. 4f, three back contact solar cells 60, 61 and 62 are shown positioned over the integrated back sheet of FIGS. 4d and 4e. In FIG. 4f, the ILD layer is not shown. Each of the solar cells have back contacts of opposite polarity on their back side that face the integrated backsheet. The back contacts are electrically connected to the metal foil circuits on the back sheet through the holes m the ILD layer and the optional encapsulant layer with which the solar cell back contacts are aligned. The solar cell back contacts may be electrically connected to the metal foil circuits by a conductive adhesive, such as Loctite 3888 and Loctite 5421 from Henkel Corporation, of Germany, that is applied in the holes or passages in the ILD layer and the optional encapsulant layer so as to electrically connect and attach the back contacts to the metal foil circuits.

The solar cells and metal foil circuits shown in FIG. 4f are simplified for purpose of illustration and show only three rows of three positive contacts and three rows of three negative contacts for each solar cell that have been connected in series. It is contemplated that each solar module could have many more individual solar cells, and that each solar cell could have fewer or more rows of back contacts, and that each row of back contacts could have fewer or more positive or negative contacts in each row than what is shown in FIG. 4f. As shown in FIG. 4f, the metal circuit 34b electrically connects the positive polarity contacts of solar cell 60 in series to the negative polarity contacts of solar cell 61, and the metal foil circuit 34c connects the positive polarity electrical contacts of solar cell 61 in series to the negative polarity contacts of solar cell 62.

In one embodiment, the solar cells are positioned on the integrated back sheet using pick and place technology which is well know in electronic circuit technology. Once the solar cells have been electrically connected to the integrated back sheet, a front encapsulant layer can be placed over the front side of the solar cell and a transparent front sheet can be placed over the front encapsulant layer. Alternatively, the solar cells can be initially placed on the front encapsulant layer before the integrated back-sheet is connected to the back side of the solar cells.

The front encapsulant layer may be comprised of any of the encapsulant materials described above with regard to the back side encapsulant layer. The transparent front sheet (also know as the incident layer) comprises one or more light-transmitting sheet or film layers. The light-transmitting front sheet may be comprised of glass or of transparent plastic sheets, such as, polycarbonate, acrylics, polyacrylate, cyclic polyolefins, such as ethylene norbornene polymers, polystyrene polyamides, polyesters, fluoropolymers and the like, and combinations thereof. Glass most commonly serves as the incident layer of the photovoltaic solar module. The term “glass” is meant to include not only window glass, plate glass, silicate glass, sheet glass, low iron glass, tempered glass, tempered CeO-free glass, and float glass, but also includes colored glass specialty glass which includes ingredients to control, for example, solar heating, coated glass with, for example, sputtered metals, such as silver or indium tin oxide, for solar control purposes, E-glass, Toroglass, Solex® glass (a product of Solutia) and the like. The type of glass to be selected for a particular laminate depends on the intended use.

A process of manufacturing the photovoltaic module, with the disclosed integrated back-sheet will now be disclosed. The photovoltaic, module may be produced through autoclave and non-autoclave processes. For example, the photovoltaic module constructs described above may be laid up in a vacuum lamination press and laminated together under vacuum with heat and standard atmospheric or elevated pressure. In an exemplary process, a glass sheet, a front-sheet encapsulant layer, a photovoltaic cell layer, a back-sheet encapsulant layer and an integrated back sheet as disclosed above are laminated together under heat and pressure and a vacuum (for example, in the range of about 27-28 inches (689-711 mm) Hg) to remove air. Preferably, the glass sheet has been washed and dried. A typical glass type is 90 mil thick annealed low iron glass. In an exemplary procedure, the laminate assembly of the present invention is placed into a bag capable of sustaining a vacuum (“a vacuum bag”), the air is drawn out of the bag using a vacuum line or other means of pulling a vacuum on the bag, the bag is sealed while maintaining the vacuum, the sealed bag is placed in an autoclave at a temperature of about 120° C. to about 180° C., at a pressure of about 200 psi (about 15 bars), for from about 10 to about 50 minutes. Preferably the bag is autoclaved at a temperature of from about 120° C. to about 160° C. for 20 minutes to about 45 minutes. More preferably the bag is autoclaved at a temperature of from about 135° C. to about 160° C. for about 20 minutes to but 40 minutes.

Air trapped within the laminate assembly may be removed through a nip roll process. For example, the laminate assembly may be heated in an oven at a temperature of about 80° C. to about 120° C., or preferably, at a temperature of between about 90° C. and about 100° C., for about 30 minutes. Thereafter, the heated laminate assembly may be passed through a set of nip rolls so that the air in the void spaces between the photovoltaic module outside layers, the photovoltaic cell layer and the encapsulant layers may be squeezed out, and the edge of the assembly sealed. This process may provide the final photovoltaic module laminate or may provide what is referred to as a pre-press assembly, depending on the materials of construction and the exact conditions utilized.

The pre-press assembly may then be placed in an air autoclave, where the temperature is raised to about 120° C. to about 160° C., or preferably, between about 135° C. and about 160° C., and the pressure is raised to between about 100 psig and about 300 psig, or preferably, about 200 psig (14.3 bar). These conditions are maintained for about 15 minutes to about 1 hour, or preferably, about 20 to about 50 minutes, after which, the air is cooled while no more air is added to the autoclave. After about 20 minutes of cooling, the excess air pressure is vented and the photovoltaic module is removed from the autoclave. The described process should not be considered limiting. Essentially, any photovoltaic module lamination process known within the art may be used to produce the back contact photovoltaic modules with integrated back sheet as disclosed herein.

If desired, the edges of the photovoltaic module may be sealed to reduce moisture and air intrusion by any means known within the art. Such moisture and air intrusion may degrade the efficiency and lifetime of the photovoltaic module. Edge seal materials include, but are not limited to, butyl rubber, polysulfide, silicone, polyurethane, polypropylene elastomers, polystyrene elastomers, block elastomers, styrene-ethylene-butylene-styrene (SEBS), and the like.

### EXAMPLES

The following Examples are intended to be illustrative of the present invention, and are not intended in any way to limit the scope of the present invention.

### Test Methods

Peel Test Method

Peel strength is a measure of adhesion of laminated sample. Peel strength is measure according to ASRM D1876 Standard and is expressed in units of N/cm. For example, when the peel strength was tested between a metal foil and a polymer substrate, the metal foil/thermoplastic adhesive/polymer substrate laminate was cut into sample strips of 2.54 cm in width and 10 cm in length, and the thermoplastic adhesive layer and the substrate were fixed respectively in the upper and lower grips of an extension meter to carry out a peeling test at a speed of 5 in/min (12.7 cm/min).

### Example 1

Metal foil adhered to polymer substrate. A 188 micron-thick Melinex™ S polyethylene terephthalate (“PET”) film was obtained from DuPont Teijin Films and was corona treated on both sides. A 35 micron-thick copper foil was obtained from Suzhou Fukuda Metal Co., Ltd of Suzhou, China. On an extrusion-lamination machine manufactured by Davis Standard a 1:1 (w/w) blend of Bynel® 22E757 ethylene methyl acrylate copolymer from E. I. du Pont de Nemours and Company of Wilmington, Del. (“DuPont”) and Nucrel® 0910 ethylene methacrylic acid copolymer resin from DuPont was extruded at an extrusion temperature of 270° C. between the copper foil and the PET film to form an interlayer adhesive film with a thickness of 100 microns. The peeling strength between the PET film and the extruded interlayer adhesive film was determined to be 0.2 N/cm. The peeling strength between the copper foil and the interlayer adhesive film was determined to be >5 N/cm

Die cutting metal foil to make conductive circuit. A flat die cutting press by Suzhou Tianhao electronic material Co., Ltd of Suzhou, China was used to cut through both the copper foil and interlayer adhesive film without cutting the underlying PET film. The copper foil and interlayer adhesive were die cut in a zig zag pattern like that shown in FIG. 4b using a like shaped double die cutting blade similar to that shown in FIG. 3. The waste segments from between the die cut blades were peeled off by a rewind roll to form separated foil circuit patterns on the polymer substrate. The PET film/interlayer adhesive/patterned copper foil was pressed a vacuum laminator at 140° C. for 15 min to improve the bonding strength between the copper foil and the PET film. The peel strength between PET film and the interlayer adhesive was >3 N/cm.

Dielectric layer laminated on conductive circuit. A protective PET film coated on one side with an acrylic adhesive was obtained from Shanghai HongXuan Material Technology Co., Ltd. of Shanghai, China. A dielectric layer was prepared by die cutting the adhesive coated PET film using a flat die cutting press by Suzhou Tianhao Electronic Material Co., Ltd of Suzhou, China. The dielectric layer was die cut with the pattern shown in FIG. 4d. The patterned dielectric layer was applied to the patterned copper foil with the adhesive layer on the dielectric layer facing the copper foil using a Cheminstruments HL-100 Hot Roll laminator at a lamination temperature of 25° C. The PET film/interlayer adhesive/patterned copper foil/self-adhesive patterned dielectric layer was suitable for use as an integrated back-sheet for a back contact solar cell.

### Comparative Example 1

Metal foil adhered to polymer substrate. A 188 micron-thick Melinex™ S polyethylene terephthalate (“PET”) film was obtained from DuPont Teijin Films and was corona treated on both sides. A 35 micron-thick copper foil was obtained from Suzhou Fukuda Metal Co., Ltd of Suzhou, China. On an extrusion-lamination machine manufactured by Davis Standard, a 1:1 (w/w) blend of Bynel® 22E757 ethylene methyl acrylate copolymer from DuPont and Nucrel® 0910 ethylene methacrylic acid copolymer resin from DuPont was extruded at an extrusion temperature of 270° C. between the copper foil and the PET film to form an interlayer adhesive film with a thickness of 100 microns.

Copper circuit formed by PCB etching process. The circuit area on copper foil was covered by a protective film of DuPont Riston® W250 photoresist polymer. The sample was put in hypochlorite solution at 45° C. (1 meter trough) to remove copper foil that was not covered by the protective film. Then, the sample was washed with water. The protective film was removed by sodium hydroxide (NaOH) solution at 45° C. (1.5 meters trough). The sample with copper circuit was then washed with water and dried at 80° C.

Roughness Testing of Circuit Edges from Example 1 and Comparative Example 1

Roughness Testing. Roughness of circuit edges were measured using an atomic force microscope using methods referenced in K Carneiro et al., “Roughness Parameters of Surfaces by Atomic Force Microscopy,” 44/1 Annals of the CIRP 517-522 (1995). The side face of the copper foil circuit edge formed by the etching process of Comparative Example 1 showed different morphology from the copper foil circuit edge of the die cut metal foil circuit of Example 1. Atomic force microscopy (AFM) was used to determine the roughness of the side face of circuit edges. AFM consists of scanning a sharp tip on the end of a flexible cantilever across a sample surface while maintaining a small, constant force. The tips typically have an end radius of 2-20 nm. Any AFM equipment such as a Veeco Dimension 3100 atomic force microscope can be used to scan the sample in tapping mode. The scan area is fixed as 5×5 μm² at any area of the side face of the circuit edges and all images have at least a resolution of 256×256 points. The AFM result is a graph containing the height value (Z) for every point. The root-means-square (RMS) is an average between the height deviations and the mean surface (Equation 1).

$$RMS = \sqrt{\frac{1}{n} {\sum }_{i = 1}^{n} {( {Z}_{i} - \overline{Z} )}^{2}} \qquad ( 1 )$$

Zᵢ is the height of the point i, and Z̅ is the height of mean surface. The RMS value was used to determine the roughness of the side surface of the circuit edges and is reported in nm units as follows.

| | | RMS roughness of side |
|---|---|---|
| Sample | Method | face of edge (nm) |
| CE1 | Etching process | >70 |
| E1 | Die cutting process | 0-40 |

### Example 2

Metal foil adhered to polymer substrate. A 188 micron-thick Melinex™ S PET film was obtained from DuPont Teijin Films and was corona treated on both side. A 38 micron-thick Tedlar® oriented polyvinyl fluoride (PVF) film obtained from DuPont was adhered to the PET film by a 30 micron thick layer of ethylene-methacrylate copolymer extruded between the PVF and PET films at an extrusion temperature of 290° C. on an extrusion-lamination machine manufactured by Davis Standard. A 35 micron-thick copper foil was obtained from SuZhou Fukuda Metal Co., Ltd of Suzhou, China. On an extrusion-lamination machine manufactured by Davis Standard, a 1:1 (w/w) blend of Bynel® 22E757 ethylene methyl acrylate copolymer from DuPont and Nucrel® 0910 ethylene methacrylic acid copolymer resin from DuPont was extruded at an extrusion temperature of 270° C. between the copper foil and the PET film to form an interlayer adhesive film with a thickness of 100 microns. The peeling strength between the PET film and the extruded interlayer adhesive film was determined to be 0.2 N/cm. The peeling strength between the copper foil and the interlayer adhesive film was determined to be >5 N/cm

Die cutting metal foil to make conductive circuit. A flat die cutting press by Suzhou Tianhao electronic material Co., Ltd of Suzhou, China was used to cut through both the copper foil and interlayer adhesive film without cutting the underlying PET film. The copper foil and interlayer adhesive were die cut in a zip zag pattern like that shown in FIG. 4b using a like shaped double die cutting blade similar to that shown in FIG. 3. The waste foil segments from between the die cut blades were peeled off by a rewind roll to form separated foil circuit patterns on the polymer substrate. The PET film/interlayer adhesive/patterned copper foil was pressed by a vacuum laminator at 140° C. for 15 min to improve the bonding strength between the copper foil and the PET film. The peel strength between PET film and the interlayer adhesive was >3 N/cm.

Dielectric layer laminated on conductive circuit. A protective PET film coated on one side with an acrylic acid adhesive was obtained from Shanghai HongXuan Material Technology Co., Ltd. of Shanghai, China. A dielectric layer was prepared by die cutting the adhesive coated PET film using a flat die cutting press by Suzhou Tianhao Electronic Material Co., Ltd of Suzhou, China. The dielectric layer was die cut with the pattern shown in FIG. 4d. The patterned dielectric layer was applied to the patterned copper foil with the adhesive layer on the dielectric layer facing the copper foil using a Cheminstruments. HL-100 Hot Roll laminator at a lamination temperature of 25° C. The PVF/interlayer adhesive/PET film/interlayer adhesive patterned copper foil self-adhesive patterned dielectric layer was suitable for use as an integrated back-sheet for a back contact solar cell.

### Example 3

Metal foil adhered to polymer substrate. A 188 micron-thick Melinex™ S PET film was obtained from DuPont Teijin Films and was corona treated on both side. A 38 micron-thick Tedlar® oriented PVF film obtained from DuPont was adhered to the PET film by a 30 micron thick layer of ethylene-methacrylate copolymer extruded between the PVF and PET films at an extrusion temperature of 290° C. on an extrusion-lamination machine manufactured by Davis Standard. A 35 micron-thick copper foil was obtained from Suzhou Fukuda Metal Co., Ltd of Suzhou, China. On an extrusion-lamination machine manufactured by Davis Standard, a 1:1 (w/w) blend of Synel® 22E757 ethylene methyl acrylate copolymer form DuPont and Nucrel® 0910 ethylene methacrylic acid copolymer resin from DuPont was extruded at an extrusion temperature of 270° C. between the copper foil and the PET film to form an interlayer adhesive film with a thickness of 100 microns. The peeling strength between the PET film and the extruded interlayer adhesive film was determined to be 0.2 N/cm. The peeling strength between the copper foil and the interlayer adhesive film was determined to be >5 N/cm.

Die cutting metal foil to make conductive circuit. A flat die cutting press by Suzhou Tianhao electronic material Co., Ltd of Suzhou, China was used to cut through both the copper foil and interlayer adhesive film without cutting the underlying PET film. The copper foil and interlayer adhesive were die cut in a zig zag pattern like that shown in FIG. 4b using a like shaped double die cutting blade similar to that shown in FIG. 3. The waste foil segments from between the die cut blades were peeled of by a rewind roll to form separated foil circuit patterns on the polymer substrate. The PET film/interlayer adhesive/patterned copper foil was pressed by a vacuum laminator at 140° C. for 15 min to improve the bonding strength between the copper foil and the PET film. The peel strength between PET film and the interlayer adhesive was >3 N/cm.

Dielectric layer laminated on conductive circuit. A 188 micron-thick Melinex™ S PET film was obtained from DuPont Teijin Films. On an extrusion-coating machine manufactured by Davis Standard, a 70 micron thick layer of Bynel® 757 ethylene-methacrylate copolymer from DuPont was extrusion-coated at 290° C. on the PET film. Then a 100 micro-thick EVA layer was extrusion-coated at 100° C. on the layer of ethylene-methacrylate copolymer to produce a PET/Bynel/EVA dielectric. A flat die cutting press by Suzhou Tianhao electronic material Co., Ltd of Suzhou, China was used to cut through the PET/Bynel/EVA dielectric in the dot pattern shown in FIG. 4d using like shaped cutting blades. The EVA side of the patterned PET/Bynel/EVA dielectric was applied to the patterned foil and laminated on a Cheminstruments HL-100 Hot Roll laminator at 140° C. at a speed of 10 m/min. The initial peel strength between the dielectric and the copper foil was 1 N/cm. The PET film/interlayer adhesive/patterned copper foil/dielectric was pressed by a vacuum laminator at 140° C. for 15 min to improve the bonding strength between the dielectric and the copper foil. The peel strength between dielectric and the patterned copper foil was 30 N/cm. The PET film/interlayer adhesive/patterned copper foil/dielectric was suitable for use as an integrated back-sheet for a back contact solar cell.

### Example 4-6

Metal foil adhered to polymer substrate. 35 micron-thick copper foils were obtained from Suzhou Fukuda Metal Co. A 188 micron-thick Melinex™ S PET film was obtained from DuPont Teijin Films and was corona treated on both side. On an extrusion-lamination machine manufactured by Davis Standard, the DuPont ethylene copolymer adhesives shown in Table 1 were extruded at the extrusion temperatures shown in Table 1 between the copper foil and the PET film to form an interlayer adhesive film with a thickness of 100 microns. The peeling strength between the PET film and the extruded interlayer adhesive film and between the interlayer adhesive film and the metal foil were measured and are reported in Table 1

TABLE 1

| | Interlayer | Extrusion | PET-Interlayer | Interlayer-Cu |
|---|---|---|---|---|
| | Adhesive | Temp./ | Peel Strength/ | Peel Strength/ |
| Example | Formulation | ° C. | N/cm | N/cm |
| Example 4 | Bynel 22E757 | 270 | >0.1 | >5 |
| Example 5 | 50% Bynel | 280 | 0.8 | >5 |
| | 22E757 + 50% | | | |
| | Nucrel 0910 | | | |
| Example 6 | 50% Bynel | 250 | 0.1 | >1 |
| | 22E757 + 50% | | | |
| | Nucrel 0910 | | | |

Die cutting metal foil to make conductive circuit. A flat die cutting press by Suzhou Tianhao electronic material Co., Ltd of Suzhou, China was used to cut through both the copper foil and interlayer adhesive film of Examples 4, 5 and 6 without cutting the underlying PET films. The copper foil and interlayer adhesive of each example were die cut in a zig zag pattern like that shown in FIG. 4b using a like shaped double die cutting blade similar to that shown in FIG. 3. The foil waste segments from between the die cut blades were peeled off by a rewind roll to form separated foil circuit patterns on the polymer substrate. The PET film/interlayer adhesive/patterned copper foil laminates were pressed by a vacuum laminator at 140° C. for 15 min to improve the bonding strength between the copper foil and the PET film.

Dielectric layer laminated on conductive circuit. A 188 micron-thick Melinex™ S PET films were obtained from DuPont Teijin Films. On an extrusion-coating machine manufactured by Davis Standard, a 70 micron-thick layer of Bynel® 757 ethylene-methacrylate copolymer from DuPont was extrusion-coated at 290° C. on each of the PET films. Then a 100 micro-thick EVA layer was extrusion-coated at 100° C. on the layer of ethylene-methacrylate copolymer for each of Examples 4, 5 and 6 to produce PET/Bynel/EVA dielectric. A flat die cutting press by Suzhou Tianhao electronic material Co., Ltd of Suzhou, China was used to cut through the PET/Bynel/EVA dielectric laminates in the dot pattern shown in FIG. 4c using like shaped cutting blades. The EVA side of the patterned PET/Bynel/EVA dielectrics were applied to the patterned foils for Examples 4, 5 and 6 and laminated on a Cheminstruments HL-100 Hot Roll laminator at 140° C. at a speed of 10 m/min. The PET film/interlayer adhesive/patterned copper foil/dielectrics were pressed by a vacuum laminator at 140° C. for 15 min to improve the bonding strength between the dielectric and the copper foil. The peel strength between dielectric and the patterned copper foil in each of Examples 4, 5 and 6 was >20 N/cm. The PET film/interlayer adhesive/patterned copper foil/dielectric laminates were suitable for use as integrated back-sheets for a back contact solar cell.

### Example 7

Die cutting metal foil on a transfer film. A 35 micron-thick copper foil was obtained from Suzhou Fukuda Metal Co. The copper film was adhered to a 100 micron-thick PET transfer film with an acrylic acid adhesive layer purchased from Shanghai HongXuan Material Technology Co., Ltd. of Shanghai, China. A flat die cutting press by Suzhou Tianhao electronic material Co., Ltd of Suzhou, China was used to cut through the copper foil without cutting the underlying PET transfer film. The copper fall was die cut in a zig zag pattern like that shown in FIG. 4b using a like shaped double die cutting blade similar to that shown in FIG. 3. The foil waste segments from between the die cut blades were peeled off by a rewind roll to form separated foil circuit patterns on the PET transfer film.

Transferring patterned metal foil to polymer substrate. A 188 micron-thick Melinex™ S PET film was obtained from DuPont Teijin Films. A 30 micron thick layer of ethylene-methacrylate copolymer (Bynel® 22E757 ethylene methyl acrylate copolymer from DuPont) was extruded between the PET film and the patterned metal foil on the PET transfer film at an extrusion temperature of 290° C. on an extrusion-lamination machine manufactured by Davis Standard. The peel strength between the interlayer adhesive and the copper foil was much stronger than that between copper foil and PET transfer film. The PET transfer film was peeled from the patterned copper foil to complete the transfer of the die cut copper foil to the PET film. The patterned copper foil/interlayer adhesive/PET film was pressed by a vacuum laminator at 140° C. for 15 min to improve the bonding strength between the copper foil and the PET film. The peel strength between the patterned copper foil and the PET film was >5 N/cm.

Dielectric layer laminated on conductive circuit. A 188 micron-thick Melinex™ S PET film was obtained from DuPont Teijin Films and was corona treated on both side. On an extrusion-coating machine manufactured by Davis Standard, a 70 micron-thick layer of Bynel® 757 ethylene-methacrylate copolymer from DuPont was extrusion-coated at 290° C. on the PET film. Then a 100 micro-thick EVA layer was extrusion-coated at 100° C. on the layer of ethylene-methacrylate copolymer to produce the PET/Bynel/EVA dielectric. A flat die cutting press by Suzhou Tianhao electronic material Co., Ltd of Suzhou, China was used to cut through the PET/Bynel/EVA dielectric in the dot pattern shown in FIG. 4d using like shaped cutting blades. The EVA side of the patterned PET/Bynel/EVA dielectric layer was applied to the patterned foil and laminated on a Cheminstruments HL-100 Hot Roll laminator at 140° C. at a speed of 10 m/min. The PET film/interlayer adhesive/patterned copper foil/dielectric layer was pressed by a vacuum laminator at 140° C. for 15 min to improve the bonding strength between the dielectric layer and the copper foil. The peel strength between dielectric layer and the patterned copper foil was >20 N/cm. The PET film interlayer adhesive patterned copper foil dielectric layer was suitable for use as integrated back-sheet for a back contact solar cell.

### Example 8

Die cutting metal foil on a transfer film. A 35 micron-thick copper foil was obtained from Suzhou Fukuda Metal Co. The cooper film was adhered to a 100 micron-thick PET transfer film with an acrylic acid adhesive layer purchased from Shanghai HongXuan Material Technology Co., Ltd. of Shanghai, China. A flat die cutting press by Suzhou Tianhao electronic material Co., Ltd of Suzhou, China was used to cut through the copper foil without cutting the underlying PET transfer film. The copper foil was die cut in a zig zag pattern like that shown in FIG. 4b using a like shaped double die cutting blade similar to that shown in FIG. 3. The foil waste segments from between the die cut blades were peeled off by a rewind roll to form separated foil circuit patterns on the PET transfer film.

Transferring patterned metal foil to polymer substrate. A PVF/PET laminate was provided. On an extrusion-lamination machine manufactured by Davis Standard, two layers of ethylene copolymer (Bynel® 22E757 ethylene methyl acrylate copolymer from DuPont and Nucrel® 0910 ethylene methacrylic acid copolymer resin from DuPont) each with a thickness of 30 microns were co-extruded at 290° C. between the PET side of the PVF/PET laminate and the patterned copper foil on the PET transfer film. The peel strength between the Bynel/Nucrel interlayer adhesive and the copper foil was much stronger than that between copper foil and the PET transfer film. The PET transfer film was peeled from the patterned copper foil to complete the transfer of the patterned copper foil to the PET/PVF laminate. The patterned copper foil/interlayer adhesive/PET/PVF laminate was pressed by a vacuum laminator at 140° C. for 15 min to improve the bonding strength between the copper foil and the PET/PVF film. The peel strength between the patterned copper foil and the PET/PVF film was >12 N/cm.

Dielectric layer laminated on conductive circuit. A 188 micron-thick Melinex™ S PET film was obtained from DuPont Teijin Films. On an extrusion-coating machine manufactured by Davis Standard, a 70 micron-thick layer of Bynel® 757 ethylene-methacrylate copolymer from DuPont was extrusion-coated at 290° C. on the PET film. Then a 100 micro-thick EVA layer was extrusion-coated at 100° C. on the layer of ethylene-methacrylate copolymer to produce a PET/Bynel/EVA dielectric. A flat die cutting press by Suzhou Tianhao Electronic Material Co., Ltd of Suzhou, China was used to cut through the PET/Bynel/EVA dielectric layer in the dot pattern shown in FIG. 4d using like shaped cutting blades. The EVA side of the patterned PET/Bynel/EVA dielectric was applied to the patterned foil and laminated on a Cheminstruments HL-100 Hot Roll laminator at 140° C. at a speed of 10 m/min. The PET film interlayer adhesive patterned copper foil dielectric layer was pressed by a vacuum laminator at 140° C. for 15 min to improve the bonding strength between the dielectric layer and the copper foil. The peel strength between dielectric layer and the patterned copper foil was >20 N/cm. The PET film/interlayer adhesive/patterned copper foil/dielectric layer was suitable for use as integrated back-sheet for a back contact solar cell.

### Example 9

Die Cutting Metal Foil on a Transfer Film

A 35 micron-thick copper foil was obtained from Suzhou Fukuda Metal Co. A low density polyethylene (LDPE 2420H obtained from CNOOC and Shell Petrochemicals Company Ltd.) was extrusion-coated at an extrusion temperature of 260° C. on the metal foil to form a 100 micron-thick transfer film. A flat die cutting press by Suzhou Tianhao Electronic Material Co., Ltd of Suzhou, China was used to cut through the copper foil without cutting the underlying LDPE transfer film. The copper foil was die cut in a zig zag pattern like that shown in FIG. 4b using a like shaped double die cutting blade similar to that shown in FIG. 3. The waste segments from between the die cut blades were peeled off by a rewind roll to form separated foil circuit patterns on the LDPE transfer film.

### Transferring Patterned Metal Foil to Polymer Substrate

A PVF/PET laminate was provided. On an extrusion-lamination machine manufactured by Davis Standard, two layers of ethylene copolymer (Bynel® 22E757 ethylene methyl acrylate copolymer from DuPont and Nucrel® 0910 ethylene methacrylic acid copolymer resin from DuPont) each with a thickness of 30 microns were co-extruded at 290° C. between the PET side of the PVF/PET laminate and the patterned copper foil on the LDPE transfer film. The peel strength between the Bynel/Nucrel interlayer adhesive and the copper foil was much stronger than that between copper foil and the LDPE transfer film. The LDPE transfer film was peeled from the patterned copper foil to complete the transfer of the patterned copper foil to the PET/PVF film. The patterned copper foil/interlayer adhesive/PET/PVF film was pressed by a vacuum laminator at 140° C. for 15 min to improve the bonding strength between the copper foil and the PET/PVF film. The peel strength between the patterned copper foil and the PET/PVF film was >12 N/cm.

Dielectric layer laminated on conductive circuit. A 188 micron-thick Melinex™ S PET film was obtained from DuPont Teijin Films. On an extrusion-coating machine manufactured by Davis Standard, a 70 micron-thick layer of Bynel® 757 ethylene-methacrylate copolymer from DuPont was extrusion-coated at 290° C. on the PET film. Then a 100 micro-thick EVA layer was extrusion-coated at 100° C. on the layer of ethylene-methacrylate copolymer to produce a PET/Bynel/EVA dielectric. A flat die cutting press by Suzhou Tianhao electronic material Co., Ltd of Suzhou, China was used to cut through the PET/Bynel/EVA dielectric in the dot pattern shown in FIG. 4d using like shaped cutting blades. The waste foil segments from between the die cut blades were peeled off. The EVA side of the patterned PET/Bynel/EVA dielectric was applied to the patterned foil and laminated on a Cheminstruments HL-100 Hot Roll laminator at 140° C. at a speed of 10 m/min. The PET film/interlayer adhesive/patterned copper foil/dielectric was pressed by a vacuum laminator at 140° C. for 15 min to improve the bonding strength between the dielectric layer and the copper foil. The peel strength between dielectric layer and the patterned copper foil was >20 N/cm. The PET film/interlayer adhesive/patterned copper foil/dielectric was suitable for use as integrated back-sheet for a back contact solar cell.

1. A process for forming an integrated back-sheet for a back contact photovoltaic module, comprising:
providing a polymer substrate and a conductive metal foil;
die cutting said conductive metal foil to separate the metal foil into two or more conductive metal foil sections;
removing one or more of said conductive metal foil sections to form one or more patterned metal foil circuits from the remaining metal foil;
adhering said conductive metal foil to said polymer substrate.

2. The process of claim 1 wherein said conductive metal foil is adhered to said polymer substrate before the conductive metal foil is die cut into two or more conductive metal foil sections, and wherein die cutting of said conductive metal foil does not cut through said polymer substrate.

3. The process of claim 1 wherein the conductive metal foil is die cut into two or more conductive metal foil sections, and one or more of said conductive metal foil sections is removed to form one or more patterned metal foil circuits, and the one or more patterned metal foil circuits is subsequently adhered to said polymer substrate.

4. The process of claim 3 wherein
the conductive metal foil is adhered to a transfer sheet prior to the steps of die cutting the metal foil and removing the one or more of said conductive metal foil sections to form one or more patterned metal foil circuits from the remaining metal foil, and
after the steps die cutting the metal foil and removing the one or more of said conductive metal foil sections to form one or more patterned metal foil circuits from the remaining metal foil, the patterned metal foil circuit is transferred from said transfer sheet and adhered to said polymer substrate.

5. The process of claim 1 wherein said conductive metal foil is adhered to said polymer substrate by a thermoplastic adhesive extruded between said conductive metal foil and said polymer substrate.

6. The process of claim 1 wherein said conductive metal foil is adhered to the polymer substrate by an extruded ethylene copolymer adhesive layer.

7. The process of claim 6 wherein said conductive metal foil is adhered to said polymer substrate before the conductive metal foil is die cut into two or more conductive metal foil sections, wherein die cutting of said conductive metal foil does not cut through said polymer substrate, wherein the die cutting said conductive metal foil to separate the metal foil into two or more conductive metal foil sections without cutting said polymer substrate also cuts the ethylene copolymer layer into sections corresponding to the sections of the conductive metal foil, and wherein the removing of one or more of said conductive metal foil sections from said polymer substrate also removes the corresponding section of the ethylene copolymer layer from the polymer substrate.

8. The process of claim 6 wherein said ethylene copolymer layer is extruded onto one of said polymer substrate, said conductive metal foil, or both said polymer substrate and said conductive metal foil in order to adhere said conductive metal foil to said polymer substrate.

9. The process of claim 1, further comprising the steps of:
providing an interlayer dielectric layer; and in any order
die cutting said interlayer dielectric layer to form holes in interlayer dielectric layer; and
adhering said interlayer dielectric layer over one or more of said patterned metal circuits that are adhered to said polymer substrate wherein said holes in the interlayer dielectric layer are aligned with said patterned metal foil circuits.

10. The process of claim 1 wherein said polymer substrate comprises a polyester layer having opposite first and second sides, wherein the first side of said polyester layer is adhered to conductive metal foil by an extruded ethylene copolymer adhesive layer.

11. The process of claim 10 wherein said polymer substrate further comprises a fluoropolymer layer adhered to the second side of said polyester layer.

12. The process of claim 1 wherein said conductive metal foil is comprised of one or more metals selected from aluminum, tin, copper, nickel, silver, gold, tin coated copper, silver coated copper, gold coated copper, steel, invar, and alloys thereof.

13. The process of claim 12 wherein the conductive metal foil has a thickness of 5-50 microns, and optionally 8-40 microns.

14. A process for forming a back contact solar module, comprising the steps:
providing the integrated back-sheet formed according to the process of claim 1;
providing a back contact photovoltaic cell having a front side and a back side, said photovoltaic cell having electrical contacts on the back side of the photovoltaic cell; and
electrically connecting electrical contacts on the back side of the photovoltaic cell to the one or more patterned metal foil circuits adhered to polymer substrate.

15. The process of claim 14 further comprising the steps of
adhering an interlayer dielectric layer over one or more of said patterned metal circuits;
die cutting said interlayer dielectric layer to separate the interlayer dielectric layer into two or more interlayer dielectric layer sections without cutting said one or more patterned metal circuits at the same time;
peeling one or more of said interlayer dielectric layer sections from said patterned metal circuit to create one or more holes in said interlayer dielectric layer through which one or more of said patterned metal circuits are exposed;
adhering the back side of the photovoltaic cell to the interlayer dielectric layer in a manner that one or more of the electrical contacts on the back side of the photovoltaic cell are electrically connected to one of said patterned metal foil circuits adhered to polymer substrate through one of said holes in said interlayer dielectric layer.

16. The process of claim 15 wherein the electrical contacts on the back side of the photovoltaic cell are electrically connected to one of said patterned metal foil circuits on said polymer substrate through one of said holes in the interlayer dielectric layer by an electrically conductive adhesive or by solder.

17. The process of claim 15 further comprising a step of applying an encapsulant layer to the back side of the photovoltaic cell, said encapsulant layer having one or more openings corresponding to the electrical contacts on the back side of the photovoltaic cell and to the one or more holes in the interlayer dielectric layer.

18. An integrated back-sheet for a back contact photovoltaic module, comprising:
a polymer substrate; and
a die cut metal foil circuit adhered to the polymer substrate by an extruded thermoplastic adhesive layer between the polymer substrate and the die cut metal foil circuit.

19. An integrated back-sheet for a back contact photovoltaic module, comprising:
a polymer substrate; and
a patterned metal foil circuit adhered to the polymer substrate by an extruded thermoplastic adhesive layer between the polymer substrate and the patterned metal foil circuit, wherein the patterned metal foil circuit is characterized by edges having side surfaces with a root-mean-square (RMS) roughness value of less than about 40 nm within a 5×5 μm² area measured by atomic force microscopy.

20. A back contact solar cell module comprising:
the integrated back-sheet of claim 19;
a back contact photovoltaic cell having a front side and a back side, said photovoltaic cell having electrical contacts on the back side of the photovoltaic cell;
an interlayer dielectric layer between the patterned metal foil circuit of the integrated backsheet and the electrical contacts on the back side of the back contact photovoltaic cell, said interlayer dielectric layer having one or more holes aligned over one or more of said patterned metal foil circuits, wherein the electrical contacts on the back side of the photovoltaic cell are electrically connected to one or more of said patterned metal foil circuits through said holes in said interlayer dielectric layer.

21. The back contact solar cell module of claim 20 wherein the patterned metal foil circuit is adhered to the polymer substrate by an extruded ethylene copolymer adhesive.
